(19) United States
(12) Patent Application Publication
(10) Pub. No.: US 2026/0304636 A1
(43) Pub. Date: Oct. 1, 2026

(54) FORMING A CIRCUIT BEARING STRUCTURE WITH LOW TEMPERATURE AND PRESSURE DURING LAMINATION CYCLE

(71) Applicant: LCP MEDICAL TECHNOLOGIES, LLC, Rogers, MN (US)

(72) Inventor: James Rathburn, Rogers, MN (US)

(21) Appl. No.: 19/478,808

(22) PCT Filed: Apr. 29, 2024
(86) PCT No.: PCT/US2024/026856

§ 371 Date: Oct. 25, 2025

Related U.S. Application Data
(60) Provisional application No. 63/498,905, filed on Apr. 28, 2023.

(51) Int. Cl. H05K 3/00; H05K 1/03; H05K 3/06; H05K 3/46

(52) U.S. Cl. CPC H05K 3/0064; H05K 1/0313; H05K 3/06; H05K 3/4602; H05K 3/4626; H05K 2201/0141

(57) ABSTRACT

Embodiments for a method of forming a circuit bearing structure are provided. The method includes pre-tacking one or more dielectric bonding sheets to a second substrate including a layer of liquid crystal polymer (LCP). The second substrate is then stacked on a first substrate to form a stack-up. The first substrate includes a layer of LCP and has circuit features standing proud on a first surface thereof. The one or more dielectric bonding sheets are disposed between the second substrate and the first substrate over the circuit features. The stack-up is then laminated with pressure lower than 300 pounds per square inch (psi) and temperature lower than 250 degrees Celsius for at least 90 percent of the time of lamination to cure the one or more dielectric bonding sheets and bond the first substrate to the second substrate.

### RELATED APPLICATIONS

This application claims the benefit of U.S. Provisional Application No. 63/498,905, filed on Apr. 28, 2023, and entitled “LOW TEMPERATURE, LOW PRESSURE LAMINATION OF LIQUID CRYSTAL POLYMER MULTI-LAYER HIGH PERFORMANCE CIRCUIT STRUCTURES”, both of which are hereby incorporated herein by reference.

### BACKGROUND

Traditional printed circuits are often constructed in either rigid or flexible formats. In a rigid format, the printed circuit board (PCB) is a laminate of materials including circuits that when completed is stiff and cannot bend significantly without damage. Flexible circuits have become popular more recently in many applications where the ability to bend the circuit to connect one member of a system to another has some benefit. These flexible circuits are made in a similar manner to rigid PCBs, where layers of circuitry and dielectric are laminated. The main difference is the material set used for construction. Typical flexible circuits start with a polymer film that is clad, laminated, or deposited with copper. A photolithography image with the desired circuit geometry is printed onto the copper, and the film is etched to remove the unwanted materials. The films are processed similar to that of rigid PCBs with a series of imaging, masking, drilling, via creation, plating, trimming, etc. The resulting circuit is flexible in such a way that as it is bent, the polymer film bends and supports the copper circuitry in a way that it does not crack or break. These circuits are solderable and can have devices attached to provide some desired function. They are used in many electronic systems such as notebook computers, medical devices, displays, handheld devices, automobiles, and aircraft. These flexible materials can be used in high frequency applications where the material set and design features can often provide better electrical performance than a comparable rigid circuit.

Both rigid and flexible circuits are connected to the system in a variety of ways. In most cases, a portion of the circuitry is exposed to create a connection point in terminal. Once exposed, the terminal can be connected to another circuit or component by soldering, conductive adhesive, thermosonic welding, pressure, or some sort of connector.

In general, the terminals are located on an end of the circuit, where edge traces are exposed or in some cases an area array of terminals are exposed. Often there is some sort of mechanical enhancement at or near the connection to prevent the joints from being disconnected during use or flexure.

Most printed circuit constructions utilize dielectrics and composites in sheet or film form, with processing steps that rely on lamination and bonding materials in sheet form to create the multi-layer stacks. As circuits and the spaces between them get smaller, it becomes increasingly difficult to control the impedance environment of the circuits. The characteristic impedance of a circuit is dictated by the circuit geometry itself, the dielectric properties of the material set surrounding the circuit, and the dielectric separation to the nearest reference plane. Existing commercially available material sets are typically provided in specific thicknesses that are held to a certain tolerance, which may be a fairly wide range depending on manufacturing variability. These material sets can also be relatively thick due to the desire for ease of handling during the manufacturing process. In some cases, a build-up film, such as Ajinomoto Build-Up Film® (ABF) produced by Ajinomoto Fine-Techno Co., Inc., is used for fine line and space substrate applications, where the circuit pattern is laser ablated into the film and plated with electroless copper and then electrolytic copper to create the circuit pattern. In this case, the dielectric film itself acts as the base dielectric and does not require a bonding layer with the next layer of ABF. ABF is one alternative that uses itself as the dielectric bearing circuits, with liquid crystal polymer (LCP) and polytetraflouroethylene (PTFE) (Teflon®) among other materials as well as many other lower loss materials that are a mixture of resin epoxy, ceramic, glass, etc.

### BRIEF DESCRIPTION

Embodiments for a method of forming a circuit bearing structure are provided. The method includes pre-tacking one or more dielectric bonding sheets to a second substrate including a layer of liquid crystal polymer (LCP). The second substrate is then stacked on a first substrate to form a stack-up. The first substrate includes a layer of LCP and has circuit features standing proud on a first surface thereof. The one or more dielectric bonding sheets are disposed between the second substrate and the first substrate over the circuit features. The stack-up is then laminated with pressure lower than 300 pounds per square inch (psi) and temperature lower than 250 degrees Celsius for at least 90 percent of the time of lamination to cure the one or more dielectric bonding sheets and bond the first substrate to the second substrate.

### DRAWINGS

Understanding that the drawings depict only exemplary embodiments and are not therefore to be considered limiting in scope, the exemplary embodiments will be described with additional specificity and detail through the use of the accompanying drawings, in which:

FIGS. 1A-1G are cross-sectional cut-away views of example stages in a process of creating a circuit bearing structure using low temperature and pressure during a lamination cycle; and FIGS. 2A and 2B are cross-sectional cut-away views of example stages in a process of adding a layer to a circuit bearing structure formed in accordance with the process of FIGS. 1A-1G.

### DETAILED DESCRIPTION

The subject matter described herein leverages the principles of traditional circuit fabrication, while using alternate dielectric materials in ink form to create a multi-layer low loss circuit stack. The dielectric ink provides an alternative or complement to existing sheet-based dielectric multi-layer circuit fabrication.

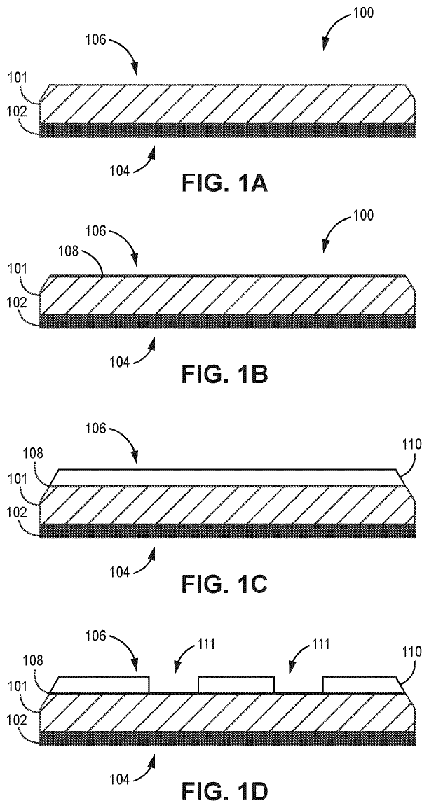

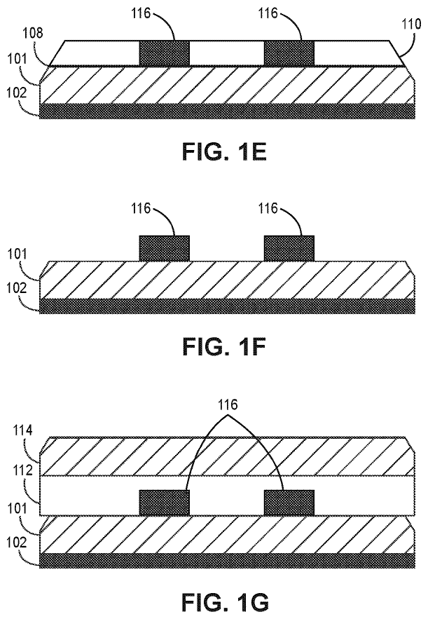

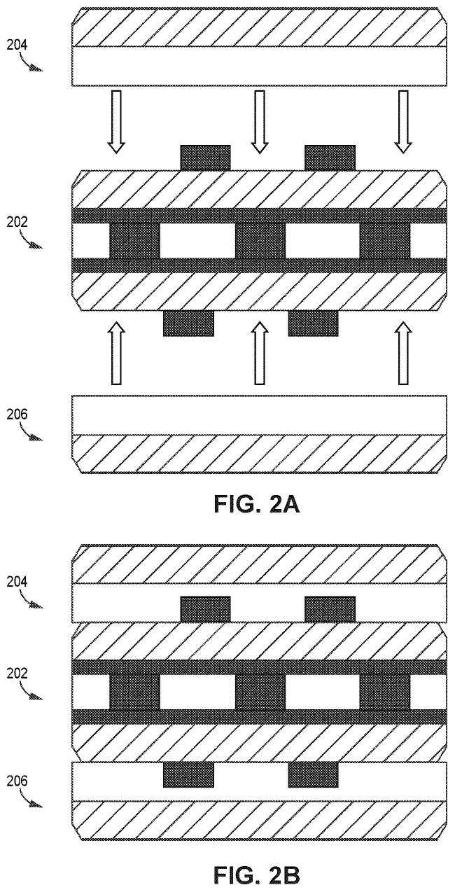

FIG. 1A is a cross-sectional cut-away view of an example portion of a substrate 100 onto which a circuit can be fabricated as described herein. The substrate 100 can include one or more dielectric layers 101. Each dielectric layer 101 can be composed of a dielectric material, such as liquid crystal polymer (LCP), polyimide, or Ajinomoto Build-Up Film® (ABF) produced by Ajinomoto Fine-Techno Co., Inc. LCP has many benefits from an electrical and mechanical standpoint. It has a lower dielectric constant than traditional PCB dielectric materials, can be processed to accept direct metal deposition, does not absorb moisture, and has low loss at high frequencies. The dielectric layer 101 can be a preformed film, or can be injection molded, printed, or compression molded to form a planar film having a desired thickness. In an example, the dielectric layer 101 is less than 200 microns thick. The composition of each dielectric layer 101 can be selected to have desired dielectric properties. One or more of the dielectric layers 101 can be clad with a copper layer 102 on a first surface 104 and have the bare dielectric layer exposed on a second surface 106, reverse of the first surface 104. The copper layer 102 can be deposited or laminated onto a dielectric layer 101 or can be a copper film that is laminated to a dielectric layer 101 and etched down to a thickness of 10 microns or less. Although FIG. 1A illustrates substrate 100 having a single dielectric layer 101 with no circuit features formed therein, in other examples the substate 100 includes more than one dielectric layer (e.g., a stack of dielectric layers) each of which may or may not have circuit features defined therein or thereon.

FIGS. 1B-1F are cross-sectional views of the example stages of forming a circuit on the substrate of FIG. 1A. In FIG. 1B, a layer of metal (e.g., copper) 108 is deposited on the second surface 106 of the dielectric layer 101. The metal layer 108 can be 10 microns or less thick, for example, between about 1 and 5 microns thick. The metal layer 108 can be formed by coating the second surface 106 of the dielectric layer 101 with particle-free metal ink. Particle-free metal ink is a liquid that includes metal ions, metal molecules, and/or metal salts along with volatile solvents in a solution. The metal ions, molecules, and/or salts can include copper and/or palladium and have a size less than 1 micron. The surface of the dielectric layer 101, can be conditioned to accept particle-free metal ink prior to coating. Conditioning the dielectric layer 101 can include roughening the surface to improve the bond between the dielectric and the particle-free ink. Some dielectrics have a smooth surface that can be adhesion resistant.

Conditioning such a surface with O₂ plasma, permanganate, or applying a primer can create a slight porosity, roughened, or activated surface that improves a chemical and mechanical bond and increases the peel strength of the bond to reduce risk of separation during use or temperature excursions.

Once the particle-free ink is coated on the surface, the particle-free metal ink can be sintered to drive metal deposition out of solution to create a layer of solid metal 108 on the second surface 106 of the dielectric layer 101. Sintering can include treating the particle-free metal ink with a thermal excursion or plasma atmosphere, which causes the metal in the particle-free metal ink to deposit as the solvent evaporates. The resultant deposition is ideally entirely bulk metal, although some oxide may be present depending on the purity of the solution and the atmosphere as the solvent is evaporated.

In an alternative example, the metal layer 108 can be formed via known electroless copper deposition techniques or can be a copper film that is laminated to the dielectric layer 101 and etched down to a thickness of 10 microns or less.

In FIG. 1C, a resist 110 is deposited on the second surface 106 on top of the metal layer 108. The resist 110 can be composed of any suitable material. In FIG. 1D, the resist 110 is imaged and stripped to cure portions of the resist that are not overtop of desired circuit locations 111 and to remove portions of the resist that are overtop of desired circuit locations 111, thereby exposing the metal layer 108 in the desired circuit locations 111.

In FIG. 1E, the resist 110 is imaged and stripped and copper is added in the recesses formed in the resist 110 to form circuit features. In an example, the copper is added via electroplating with the layer of metal 108 as the electrical bus. In this example, the resist 110 restricts the deposition of copper to the recesses, forming circuit features 116 on top of the dielectric layer 101. In an alternative example, copper can be added to the recesses via additional coating of the surfaces of the recesses with particle-free metal ink and sintering.

In FIG. 1F, the resist 110 is stripped away after plating and the layer of metal 108 outside of the circuit features 116 is also etched away. This leaves circuit features 116 standing proud on the surface of the dielectric layer 101 without metal extending between adjacent circuit features 116.

FIG. 1G is a cross-sectional view of a step in which an additional dielectric layer 114 is added over top of the circuit features 116. In such a step, a dielectric sheet 112 is pre-tracked to the additional dielectric layer 114. The dielectric sheet 112 acts as the physical bonding medium between the (e.g., LCP) dielectric layers 101, 114. The dielectric sheet 112 is not cured during the pre-tacking process such that it can be cured later during a final lamination to bond together the dielectric layers 101, 114. In some examples, multiple dielectric sheets 112 are pre-tacked to the additional dielectric layer 114 to provide increased thickness between dielectric layers 101, 114. The additional dielectric layer 114 with the dielectric sheet 112 pre-tacked thereto can then be placed on the second surface 106 of the substrate 101. If additional layers are desired for the stack-up, circuit features can be formed in or on the dielectric layer 114 in the same manner described above with respect to FIGS. 1A-1F prior to adding the additional layers. The additional layers can be then added in the same manner as described above by pre-tacking one or more dielectric sheets 112 to an additional dielectric layer 114 and disposing the additional dielectric layer 114 on the circuit stack-up with the pre-tacked dielectric sheets 112 disposed between the additional dielectric layer 114 and the existing circuit-stack up. This process of forming circuit features in a dielectric layer 114 and adding addition dielectric layers 114 can be repeated as desired on either or both sides 104, 106 of substrate 101 to add the desired circuit layers to the circuit stack-up.

Once the desired circuit layers are present in the circuit stack-up, all the layers can be bonded together in a single lamination step. This lamination step applies temperature and pressure to the circuit stack-up such that each of the pre-tacked dielectric sheets 112 begins to flow around any circuit features standing proud on a corresponding dielectric layer 114. The circuit stack-up is then allowed to cool, curing the dielectric sheets 112 and bonding adjacent dielectric layers 114 together.

LCP as the dielectric layer 114 is soft and has a relatively low melting point. Thus, when using LCP or other dielectrics as the dielectric layer 114, the lamination step can be performed with low temperature and pressure in order to reduce loss of structural integrity of the (e.g., LCP) dielectric layers 114. Lamination is performed such that the pressure is less than 300 pounds per square inch (psi) for at least 90 percent of the lamination cycle. In an example, the lamination is maintained between 200 and 300 psi for the at least 60 minutes of the lamination cycle. Temperatures of less than 250 degrees Celsius can also be maintained for at least 90 percent of the lamination cycle. In an example, temperatures between 150 degrees Celsius and 220 degrees Celsius can be maintained for at least 60 minutes of the lamination cycle. This keeps the lamination temperature below the melt temperature of LCP, which can be around 300 to 321 degrees Celsius. The lamination cycle can be performed for between 1 and 5 hours including time to ramp up and hold the temperature and cool down afterward.

The dielectric bonding sheets 112 can be composed of a thermoset polymer having a B (partially cured) stage and a C (fully cured) stage after lamination. Suitable thermoset polymers are those that will reflow while in the B stage but will no longer reflow while in the C stage at the lamination temperatures and pressures discussed herein. Example material that can be used for the dielectric bonding sheets 112 includes Felios R-BM17 bonding material from Panasonic, fastRise™ resins from AGC Multi Materials, Pyaralux HP Series resins from DuPont, AS-400HS resin from Resonac, and ADFLEMA bond films from Namics.

In an alternative example, each additional dielectric layer 114 and corresponding bonding sheet(s) 112 can be laminated to the circuit stack in a separate lamination cycle or two additional dielectric layers 114, one on each side 104, 106 of the substrate 101 can be laminated to the substrate 101 in a single lamination cycle. Additional layers 114 can then be added via subsequent lamination cycles.

In another alternative example, additional circuit layers can be added to a substrate 101 or circuit stack by placing one or more bonding dielectric sheets 112 as described herein on a surface 104, 106 of the substrate 101 or circuit stack, fully curing the one or more bonding sheets 112, and then forming addition circuit features in or on the bonding sheets 112 using the process described above in FIGS. 1A-1F. Additional layers can then be added to the circuit stack using any of the of the processes described herein.

FIGS. 2A and 2B are cross-sectional cut-away views of another example structure (e.g., PCB) including a core 202 in which additional layers 204, 206 are added to both sides of the core 202. One or more (e.g., all) of the additional dielectric layers 204, 206 can have a thickness of less than 200 microns and can be added using the low pressure process described herein.

The core 206 includes circuit features and vertical solid copper vias for creating the desired circuit network through the stack and terminating to surface mounting pads (not shown), One or more additional layers 204, 206 can be bonded to the core 202 using respective bonding sheets 208 in a single low temperature and pressure lamination as discussed with respect to FIG. 1G.

Vertical vias can be formed through each such bonding layer 210 with laser ablation.

The side walls of recesses formed through a bonding layer 210 with laser ablation can be coated with copper (e.g., via electroless plating) and then additional copper can be electrolytically plated thereon to create a solid copper via electrically coupling an upper circuit to a lower circuit.

Although a certain type, size, and number of dielectric layers and circuit bearing structures are shown in FIGS. 1-2 herein, it should be understood that any number, size, or type of layers and/or circuit bearing structures in or on a layer can be created using the processes described herein, unless specifically limited by the corresponding description.

There are many benefits to the subject matter described herein. As high-speed circuit assemblies encounter smaller and smaller circuit geometries and spacing, conventional film or laminate based dielectric materials are challenged to meet impedance requirements due to commercially available thickness and loss properties. In addition, lamination temperatures and pressures can drive mechanical, delamination and flatness issues when trying to fill in between circuit traces and provide a strong mechanical bond between layers. Traditional LCP circuit fabrication relies on lamination temperatures and pressures that cause the LCP layers to reach near the melt temperature which is difficult to control with high risk of poor bond, delamination, material movement and geometry tolerance accumulations. In addition, LCP historically has been difficult to build in multi-layer circuit stacks with a one-time sequence rather than multiple sequential laminations accomplished with other conventional material constructions. The subject matter described herein addresses these traditional challenges and takes advantage of the mechanical and electrical properties for high speed, fine line and space, high layer count circuit assemblies. The subject matter described herein provides the ability to provide a bonding layer that con provide reliable bond strength within an LCP circuit structure with a lamination recipe that does not encroach upon the melt temperature of LCP and lowers the lamination pressure. The lamination cycle does this with materials that were developed for dielectric materials that are harder than the comparatively soft LCP.

What is claimed is:

1. A method of forming a circuit bearing structure, the method comprising:
providing a first substrate having a first dielectric layer defining a first surface and first circuit features standing proud on the first surface, wherein the first dielectric layer is composed of liquid crystal polymer (LCP);
providing a second substrate having a second dielectric layer, the second dielectric layer composed of LCP;
pre-tacking a first one or more dielectric bonding sheets to the second substrate;
stacking the second substrate on the first substrate to form a first stack-up, such that the first one or more dielectric bonding sheets are disposed between the second substrate and the first substrate and on the first surface of the first substrate over the first circuit features on the first surface; and
laminating the first stack-up with pressure lower than 300 pounds per square inch (psi) and temperature lower than 250 degrees Celsius for at least 90 percent of the time of lamination to cure the first one or more dielectric bonding sheets and bond the first substrate to the second substrate.

2. The method of claim 1, wherein laminating the stack-up forms a third substrate, the method comprising:
forming second circuit features in or on an exposed surface of the second dielectric layer;
providing a fourth substrate having a third dielectric layer, the third dielectric layer composed of LCP;
pre-tacking a second one or more dielectric bonding sheets to the third substrate;
stacking the fourth substrate on the third substrate to form a second stack-up, such that the second one or more dielectric bonding sheets are disposed between the third substrate and the fourth substrate and on the exposed surface of the second dielectric layer of the third substrate over the second circuit features in or on the exposed surface; and
laminating the second stack-up with pressure lower than 300 pounds per square inch (psi) and temperature lower than 250 degrees Celsius for at least 90 percent of the time of lamination to cure the second one or more dielectric bonding sheets and bond the fourth substrate to the third substrate.

3. The method of claim 1, comprising:
providing a third substrate having a third dielectric layer, the third dielectric layer composed of LCP;
pre-tacking a second one or more dielectric bonding sheets to the third substrate;
wherein stacking including stacking the third substrate on the first substrate along with the second substrate to form the first stack-up, such that the second one or more dielectric bonding sheets are disposed between the third substrate and the first substrate and on a surface of the first substrate opposite the first surface; and
laminating the first stack-up with pressure lower than 300 pounds per square inch (psi) and temperature lower than 250 degrees Celsius for at least 90 percent of the time of lamination to cure the first and second one or more dielectric bonding sheets and bond together the first, second, and third substrates.

4. The method of claim 1, comprising:
forming second circuit features in or on an exposed surface of the second dielectric layer;
providing a third substrate having a third dielectric layer, the third dielectric layer composed of LCP;
pre-tacking a second one or more dielectric bonding sheets to the third substrate;
wherein stacking including stacking the third substrate on the second substrate after stacking the second substrate on the first substrate to form the first stack-up which includes the first, second, and third substrates, wherein the first one or more dielectric bonding sheets are disposed between the second substrate and the first substrate and on the first surface of the first substrate, wherein the second one or more dielectric bonding sheets are disposed between the third substrate and the fourth substrate and on the exposed surface of the second dielectric layer of the second substrate over the second circuit features in or on the exposed surface; and
laminating the first stack-up with pressure lower than 300 pounds per square inch (psi) and temperature lower than 250 degrees Celsius for at least 90 percent of the time of lamination to cure the first and second one or more dielectric bonding sheets and bond together the first, second, and third substrates.

5. The method of claim 1, wherein the first dielectric layer is less than 200 microns thick and the one or more dielectric bonding layers are collectively less than 200 microns thick.

6. A method of forming a circuit bearing structure, the method comprising:
providing a first substrate having a first dielectric layer defining a first surface and first circuit features standing proud on the first surface, wherein the first dielectric layer is composed of liquid crystal polymer (LCP);
stacking one or more dielectric bonding sheets on the first surface of the first substrate over the first circuit features on the first surface;
laminating the one or more bonding sheets to the substrate with pressure lower than 300 pounds per square inch (psi) and temperature lower than 250 degrees Celsius for at least 90 percent of the time of lamination to cure the one or more dielectric bonding sheets and bond the one or more dielectric bonding sheets to the first substrate, wherein laminating forms a second substrate having a layer of cured bonding sheets, wherein the layer of cured bonding sheets has an exposed surface; and
forming second circuit features in or on the exposed surface of the layer of cured bonding sheets.

7. The method of claim 6, wherein the first dielectric layer is less than 200 microns thick and the one or more dielectric bonding layers are collectively less than 200 microns thick.
